(19) United States
(12) Patent Application Publication
(10) Pub. No.: US 2024/0057431 A1
(43) Pub. Date: Feb. 15, 2024

(54) DISPLAY DEVICE

(71) Applicant: Electronics and Telecommunications Research Institute, Daejeon (KR)

(72) Inventor: Hyunsu CHO, Daejeon (KR)

(73) Assignee: Electronics and Telecommunications Research Institute, Daejeon (KR)

(21) Appl. No.: 18/344,518

(22) Filed: Jun. 29, 2023

(30) Foreign Application Priority Data
Aug. 11, 2022 (KR) 10-2022-0100576

(51) Int. Cl. H10K 59/35

(52) U.S. Cl. CPC H10K 59/353

(57) ABSTRACT

A display device includes a first pixel and a second pixel, which are disposed adjacent to each other in a first direction and are alternately and repeatedly arranged. The first pixel includes a first sub-pixel, a second sub-pixel, and two third sub-pixels, which are arranged in a 2×2 matrix form. The second pixel includes a fourth sub-pixel, a fifth sub-pixel, and two sixth sub-pixels, which are arranged in a 2×2 matrix form. The first to third sub-pixels include sub-pixels having colors different from each other. The fourth to sixth sub-pixels include sub-pixels having colors different from each other. The first sub-pixel and the fourth sub-pixel include sub-pixels having the same color. The second sub-pixel and the fifth sub-pixel include sub-pixels having the same color. The third sub-pixels and the sixth sub-pixels include sub-pixels having the same color. The first pixel and the second pixel have a line symmetry relationship.

### CROSS-REFERENCE TO RELATED APPLICATIONS

This U.S. non-provisional patent application claims priority under 35 U.S.C. § 119 of Korean Patent Application No. 10-2022-0100576, filed on Aug. 11, 2022, the entire contents of which are hereby incorporated by reference.

### BACKGROUND

The present disclosure herein relates to a display device.

Currently, virtual reality (VR) devices and augmented reality (AR) devices are in the limelight as next-generation displays. As displays used for the above-described devices, micro displays are receiving a lot of attention. The micro displays may be largely classified into liquid crystal on silicon (LCoS) using a liquid crystal and OLED on Silicon (OLEDoS) using an organic light-emitting diode (OLED). In the case of the OLEDoS, a CMOS process is required to form fine pixels, and OLED elements are formed on electrodes formed by the CMOS process. In the OLEDoS, to implement each of red, green, and blue colors, there is a method for generally manufacturing a white OLED to implement each color through a color filter.

### SUMMARY

The present disclosure provides a pixel arrangement and a structure of a display device having high resolution.

An embodiment of the inventive concept provides a display device including: a substrate; and a first pixel and a second pixel, which are disposed adjacent to each other in a first direction parallel to a top surface of the substrate and are alternately and repeatedly arranged, wherein the first pixel includes a first sub-pixel, a second sub-pixel, and two third sub-pixels, which are arranged in a 2×2 matrix form, the second pixel includes a fourth sub-pixel, a fifth sub-pixel, and two sixth sub-pixels, which are arranged in a 2×2 matrix form, the first to third sub-pixels include sub-pixels having colors different from each other, the fourth to sixth sub-pixels include sub-pixels having colors different from each other, the first sub-pixel and the fourth sub-pixel include sub-pixels having the same color, the second sub-pixel and the fifth sub-pixel include sub-pixels having the same color, the third sub-pixels and the sixth sub-pixels include sub-pixels having the same color, and the first pixel and the second pixel have a line symmetry relationship based on a virtual line between the first pixel and the second pixel.

In an embodiment, the third sub-pixels may be disposed in different rows and different columns, and the sixth sub-pixels may be disposed in different rows and different columns.

In an embodiment, the first sub-pixel and the second sub-pixels may be disposed in different rows and different columns, and the fourth sub-pixel and the fifth sub-pixels may be disposed in different rows and different columns.

In an embodiment, one of the third sub-pixels may be disposed adjacent to one of the sixth sub-pixels in the first direction, and the other of the third sub-pixels and the other of the sixth sub-pixels may be disposed to be spaced apart from each other in the first direction with the second sub-pixel and the fifth sub-pixel therebetween.

In an embodiment, the second sub-pixel and the fifth sub-pixel may be disposed adjacent to each other in the first direction.

In an embodiment, the third sub-pixels may be disposed in different rows and the same column,
the sixth sub-pixels are disposed in different rows and the same column, and the third sub-pixels and the sixth sub-pixels may be disposed adjacent to each other.

In an embodiment, the first sub-pixel and the second sub-pixel may be disposed in different rows and the same column, and the fourth sub-pixel and the fifth sub-pixel may be disposed in different rows and the same column.

In an embodiment of the inventive concept, a display device includes: a substrate; a pair of first pixel lines disposed adjacent to each other in a first direction parallel to a top surface of the substrate; and a pair of second pixel lines disposed adjacent to each other in the first direction, wherein one of the first pixel lines is disposed adjacent to one of the first pixel lines in the first direction, and the first pixel lines and the second pixel lines are alternately and repeatedly arranged in the first direction, each of the first pixel lines includes two red sub-pixels and two first blue sub-pixels, which are alternately and repeatedly arranged in a second direction that is parallel to the top surface of the substrate and crosses the first direction, and each of the second pixel lines includes two second blue sub-pixels and two green sub-pixels, which are alternately and repeatedly arranged in the second direction.

In an embodiment, the red sub-pixels of the pair of first pixel lines may be disposed adjacent to each other in a 2×2 matrix form, the blue sub-pixels of the pair of first pixel lines may be disposed adjacent to each other in a 2×2 matrix form, the green sub-pixels of the pair of second pixel lines may be disposed adjacent to each other in a 2×2 matrix form, and the blue sub-pixels of the pair of second pixel lines may be disposed adjacent to each other in a 2×2 matrix form.

In an embodiment, one blue sub-pixel of the first pixel lines may be adjacent to one blue sub-pixel of the second pixel lines in a diagonal direction.

In an embodiment, one blue sub-pixel of the first pixel lines may be adjacent to one blue sub-pixel of the second pixel lines in the first direction.

In an embodiment, one red sub-pixel of the first pixel lines may be adjacent to one green sub-pixel of the second pixel lines in the first direction.

In an embodiment of the inventive concept, a display device includes: a substrate; a plurality of first electrodes arranged in a matrix form on the substrate; a red emission pattern, a green emission pattern, and a blue emission pattern, which are disposed on the first electrodes; and a second electrode disposed on the red, green, and blue emission patterns, wherein the red emission pattern vertically overlaps four first electrodes, which are disposed adjacent to each other in a first direction parallel to a top surface of the substrate, a second direction parallel to the top surface of the substrate and crossing the first direction, and a third direction between the first direction and the second direction, the green emission pattern vertically overlaps four first electrodes, which are disposed adjacent to each other in the first direction, the second direction, and the third direction, and the blue emission pattern vertically overlaps four first electrodes, which are disposed adjacent to each other in the first direction, the second direction, and the third direction.

In an embodiment, the display device may further include: a common layer between the plurality of first electrodes and the red, green, and blue emission patterns; a first resonance control pattern and a second resonance control pattern between the plurality of first electrodes and the common layer; and a first reflection control pattern and a second reflection control pattern on the second electrode, wherein the first resonance control pattern and the first reflection control pattern may be provided on the four first electrodes that vertically overlap the red emission pattern, and the second resonance control pattern and the second reflection control pattern may be provided on the four first electrodes that vertically overlap the green emission pattern.

In an embodiment, a thickness of the first resonance control pattern and a thickness of the second resonance control pattern may be different from each other.

In an embodiment, the display device may further include: a third resonance control pattern disposed between the plurality of first electrodes and the common layer; and a third reflection control pattern provided on the second electrode, wherein the third resonance control pattern and the third reflection control pattern may be provided on the four first electrodes that vertically overlap the blue emission pattern.

In an embodiment, the display device may further include a first pixel, a second pixel, a third pixel, and a fourth pixel, which are arranged in a clockwise direction in a 2×2 matrix form on the top surface of the substrate, wherein each of the first to fourth pixels may include one first red sub-pixel, one green sub-pixel, and two blue sub-pixels, which are arranged in a 2×2 matrix form, and the sub-pixels having the same color of each of the first to fourth pixels may be disposed adjacent to each other based on a central point at which the first pixel, the second pixel, the third pixel, and the fourth pixel are gathered.

In an embodiment, the first pixel and the second pixel may have a line symmetry relationship based on a virtual line between the first pixel and the second pixel, the first pixel and the third pixel may have a point symmetry relationship based on a virtual point between the first pixel and the third pixel, and the first pixel and the fourth pixel may have a line symmetry relationship based on a virtual line between the first pixel and the fourth pixel.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view illustrating a display device according to an embodiment of the inventive concept;

FIG. 2A is a cross-sectional view taken along line X-X′ of FIG. 1;

FIG. 2B is a cross-sectional view taken along line Y-Y′ of FIG. 1;

FIG. 3A is a cross-sectional view taken along line X-X′ of FIG. 1 according to some embodiments;

FIG. 3B is a cross-sectional view taken along line Y-Y′ of FIG. 1 according to some embodiments;

FIG. 4A is a cross-sectional view taken along line X-X′ of FIG. 1 according to some embodiments;

FIG. 4B is a cross-sectional view taken along line Y-Y′ of FIG. 1 according to some embodiments;

FIG. 5A is a cross-sectional view taken along line X-X′ of FIG. 1 according to some embodiments;

FIG. 5B is a cross-sectional view taken along line Y-Y′ of FIG. 1 according to some embodiments;

FIG. 6 is a plan view of a display device according to embodiments of the inventive concept; and

FIG. 7 is a cross-sectional view taken along line Y-Y′ of FIG. 6.

### DETAILED DESCRIPTION

Embodiments of the present invention will be described with reference to the accompanying drawings so as to sufficiently understand constitutions and effects of the present invention. The present disclosure may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. In the accompanying drawings, the components are shown enlarged for the sake of convenience of explanation, and the proportions of the components may be exaggerated or reduced for clarity of illustration.

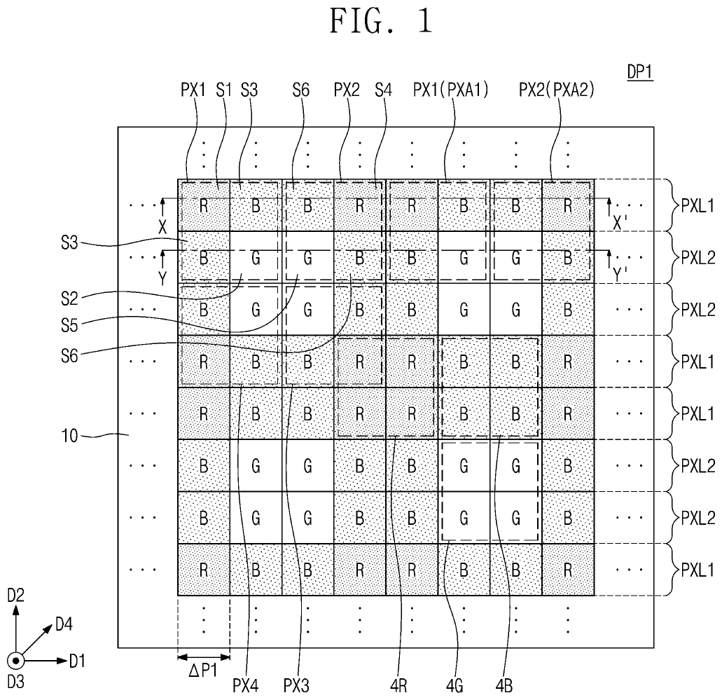

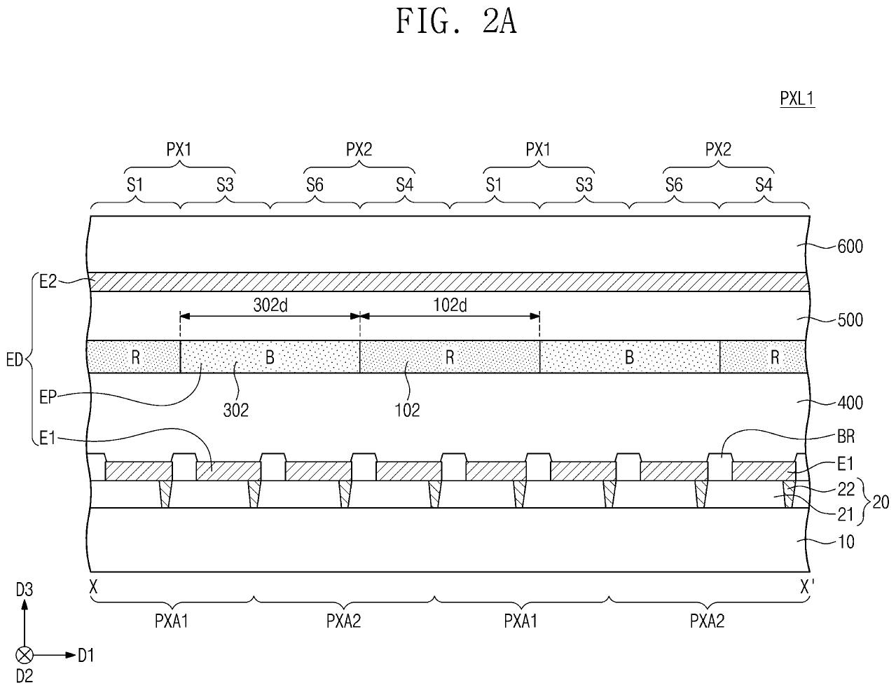

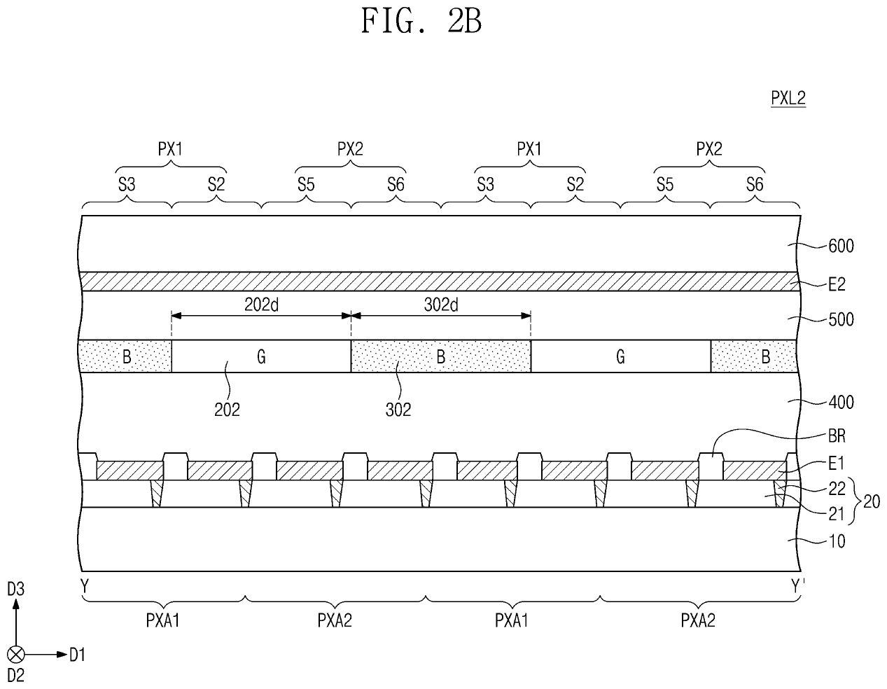

FIG. 1 is a plan view illustrating a display device according to an embodiment of the inventive concept. FIG. 2A is a cross-sectional view taken along line X-X′ of FIG. 1. FIG. 2B is a cross-sectional view taken along line Y-Y′ of FIG. 1.

Referring to FIGS. 1, 2A, and 2B, a display device DP1 according to an embodiment of the inventive concept may include a substrate 10, a line layer 20, a light emitting element ED, a first common layer 400, a second common layer 500, and a thin-film encapsulation layer 600. The substrate 10 may be, for example, a semiconductor substrate on which a circuit layer including a CMOS circuit is disposed on an upper portion thereof. The circuit layer may include data lines, scan lines, capacitors, and a plurality of transistors.

The line layer 20 may include an insulating layer 21 and a line pattern 22 in the insulating layer 21. The line pattern 22 includes a via and may serve to electrically connect the circuit layer to the light emitting element ED.

The display device DP1 may include a first pixel PX1, a second pixel PX2, a third pixel PX3, and a fourth pixel PX4, which are arranged in a clockwise direction.

The first pixel PX1 may include a first sub-pixel S1, a second sub-pixel S2, and two third sub-pixels S3, which are arranged in the form of a 2×2 matrix. The first to third sub-pixels S1 to S3 may be sub-pixels having different colors. According to some embodiments, the first sub-pixel S1 may be a red sub-pixel R, the second sub-pixel S2 may be a green sub-pixel G, and the third sub-pixel S3 may be a blue sub-pixel B.

The second pixel PX2 may include a fourth sub-pixel S4, a fifth sub-pixel S5, and two sixth sub-pixels S6, which are arranged in the form of a 2×2 matrix. The first to third sub-pixels S1 to S3 may be sub-pixels having different colors. According to some embodiments, the fourth sub-pixel S4 may be a red sub-pixel R, the fifth sub-pixel S5 may be a green sub-pixel G, and the sixth sub-pixel S6 may be a blue sub-pixel B.

As illustrated in FIG. 1, the first sub-pixel S1 and the fourth sub-pixel S4 may be sub-pixels having the same color (e.g., red color). The second sub-pixel S2 and the fifth sub-pixel S5 may be sub-pixels having the same color (e.g., green color). The third sub-pixels and the sixth sub-pixels may be sub-pixels having the same color (e.g., blue color).

In the first pixel PX1, the third sub-pixels S3 may be disposed in a diagonal direction D4. That is, the third sub-pixels S3 may be arranged in different rows and columns. In addition, the first sub-pixel S1 and the second sub-pixel S2 may be disposed in different rows and different columns. That is, the first sub-pixel S1 and the second sub-pixel S2 may be disposed in different rows and columns, respectively.

In the second pixel PX2, the sixth sub-pixels S6 may be disposed in the diagonal direction D4. That is, the sixth sub-pixels S6 may be arranged in different rows and different columns. In addition, the fourth sub-pixel S4 and the fifth sub-pixel S5 may be disposed in different rows and different columns. That is, the fourth sub-pixel S4 and the fifth sub-pixel S5 may be disposed in different rows and columns, respectively.

One of the third sub-pixels S3 may be disposed adjacent to one of the sixth sub-pixels S6 in the first direction D1 parallel to a top surface of the substrate 10. The other of the third sub-pixels S3 may be disposed to be spaced apart from the other of the sixth sub-pixels S6 in the first direction D1 with the second sub-pixel S2 and the fifth sub-pixel S5 interposed therebetween.

The first pixel PX1 and the second pixel PX2 may have a line symmetry relationship or a mirror image relationship based on a virtual line therebetween. The first pixel PX1 may have a point-symmetry relationship with the third pixel PX3 based on a central point therebetween. The first pixel PX1 may have a line symmetry relationship or a mirror image relationship with the fourth pixel PX4 based on a virtual line therebetween.

Referring to FIG. 1, the display device DP1 may include a first pixel line PXL1 and a second pixel line PXL2, which extend in the first direction D1. A pair of first pixel lines PXL1 may be disposed adjacent to each other in a second direction D2 that is parallel to the top surface of the substrate 10 and crosses the first direction D1. A pair of second pixel lines PXL2 may be disposed adjacent to each other in the second direction D2. The pair of first pixel lines PXL1 and the pair of second pixel lines PXL2 may be repeatedly and alternately arranged. The first pixel line PXL1 and the second pixel line PXL2 may include sub-pixels having different colors, respectively. For example, the first pixel line PXL1 may include two red sub-pixels R and two continuous blue sub-pixels B, which are continuously and repeatedly arranged in the first direction D1 (RRBB). The second pixel line PXL2 may include two green sub-pixels G and two blue sub-pixels B, which are continuously and repeatedly arranged in the first direction D1 (GGBB).

Each of the first pixel lines PXL1 may have a shape in which a pair of blue sub-pixels B, which are continuously arranged in the first direction D1, and a pair of red sub-pixels R, which are continuously arranged in the first direction D1, are repeatedly arranged. Each of the second pixel lines PXL2 may have a shape in which a pair of blue sub-pixels B, which are continuously arranged in the first direction D1, and a pair of green sub-pixels G, which are continuously arranged in the first direction D1, are repeatedly arranged.

The blue sub-pixel B of one first pixel line PXL1 may be disposed adjacent to the blue sub-pixel B of the other first pixel line PXL1 in the second direction D2. The red sub-pixel R of one first pixel line PXL1 may be disposed adjacent to the red sub-pixel R of the first pixel line PXL2 in the second direction D2.

The blue sub-pixel B of one second pixel line PXL2 may be disposed adjacent to the blue sub-pixel B of the second pixel line PXL2 in the second direction D2. The green sub-pixel G of one second pixel line PXL2 may be disposed adjacent to the green sub-pixel G of the second pixel line PXL2 in the second direction D2.

The blue sub-pixel B of one first pixel line PXL1 may be disposed in a diagonal direction with the blue sub-pixel B of the adjacent second pixel line PXL2. The red sub-pixel R of one first pixel line PXL1 may be disposed in a diagonal direction with the green sub-pixel G of the adjacent second pixel line PXL2.

Four red sub-pixels 4R, four green sub-pixels 4R, and four blue sub-pixels 4B, which are disposed adjacent to each other by the arrangement of the pair of first pixel lines PXL1 and the pair of second pixel lines PXL2, are provided.

Each of the four red sub-pixels 4R, the four green sub-pixels 4G, and the four blue sub-pixels 4B may be arranged in a 2×2 matrix form.

Referring to FIGS. 1, 2A and 2B, the substrate 10 may include a first pixel area PXA1 and a second pixel area PXA2, which are repeatedly arranged in the first direction D1. Although not shown, the substrate 10 may include a third pixel area and a fourth pixel area, which are repeatedly arranged in the first direction D1. The first pixel area PXA1 and the second pixel area PXA2, the third pixel area, and the fourth pixel area may be areas on which the first pixel PX1, the second pixel PX2, the third pixel PX3, and the fourth pixel PX4 are disposed, respectively.

Four light emitting elements ED may be provided on the first pixel area PXA1, the second pixel area PXA2, the third pixel area, and the fourth pixel area of the substrate 10, respectively. Each of the light emitting elements ED may include a first electrode E1, a second electrode E2, and an emission pattern EP between the first electrode E1 and the second electrode E2.

The first electrode E1 may be a pixel electrode and may function as, for example, an anode. The first electrodes E1 may be reflective electrodes. Each of the first electrodes E1 may include any one of Al, Al/Cu, and Al/TiN having high light reflectivity. Preferably, each of the first electrodes E1 may include Al/TiN. An insulating pattern BR may be disposed between the first electrodes E1 to prevent the pixel electrodes 201 from being in contact with each other.

The second electrode E2 may be disposed on the first electrode E1. The second electrode E2 may be a common electrode and may function as a cathode. The second electrode E2 may include at least one of a transparent conductive material (TCO) such as ITO and IZO that are capable of transmitting light or a semi-transmissive conductive material such as magnesium (Mg), silver (Ag), or an alloy of magnesium (Mg) and silver (Ag).

The emission pattern EP may be one of a red emission pattern 102, a green emission pattern 202, and a blue emission pattern 202. The emission pattern EP may include a host material and a dopant material. The emission pattern EP may be formed by using a phosphorescent or fluorescent light emitting material as a dopant in the host material.

The emission pattern EP may vertically overlap the two first electrodes E1 in the first direction D1 and vertically overlap the two first electrodes E1 in the second direction D2. That is, the emission pattern EP may vertically overlap the four first electrodes E1 at the same time.

A width of the emission pattern EP in the first direction D1 or in the second direction D2 may be greater about twice than the pixel pitch ΔP1 of FIG. 1. A width 102d of the red emission pattern 102 in the first direction D1 may be greater about twice than a width ΔP1 of the red sub-pixel R in the first direction D1. A width 202d of the green emission pattern 202 in the first direction D1 may be greater about twice than a width ΔP1 of the green sub-pixel G in the first direction D1. A width 302d of the blue light emitting pattern 302 in the first direction D1 may be greater about twice than a width ΔP1 of the blue sub-pixel B in the first direction D1. A planar area of the emission pattern EP may be greater about 4 times than respective planar areas of the red, green, and blue sub-pixels R, G, and B.

The first common layer 400 may be disposed between the first electrodes E1 and the emission pattern EP. The first common layer 400 may include a hole injection layer (not shown) and a hole transport layer (not shown). Each of the hole injection layer and the hole transport layer may be provided as a laminated structure or a single layer. In the case of the laminated structure, the hole injection layer may be disposed closer to the first electrodes E1, and the hole transport layer may be disposed farther from the first electrodes E1. The first common layer 401 may further include a hole buffer layer (not shown) or the like.

The second common layer 500 may be disposed between the emission pattern EP and the second electrode E2. The second common layer 500 may include an electron injection layer (not shown) and an electron transport layer (not shown). Each of the electron injection layer and the electron transport layer may be provided as a laminated structure or a single layer. In the case of the laminated structure, the electron injection layer may be disposed closer to the second electrode E2, and the electron transport layer may be disposed farther from the second electrode E2. The second common layer 500 may further include a layer such as a hole blocking layer.

The thin-film encapsulation layer 600 may be provided on the second electrode E2. The thin-film encapsulation layer 600 may include a single inorganic layer (not shown) or a first inorganic layer (not shown), an organic layer (not shown), and a second inorganic layer (not shown), which are sequentially laminated. The organic layer may be disposed between the first inorganic layer and the second inorganic layer. The first inorganic layer and the second inorganic layer may be formed by depositing an inorganic material, and the organic layer may be formed by depositing, printing, or applying an organic material. The inorganic layer (the single inorganic layer, the first inorganic layer, and the second inorganic layer) may protect the organic emission layer against moisture and oxygen, and the organic layer may protect the organic emission layer against foreign substances such as dust particles.

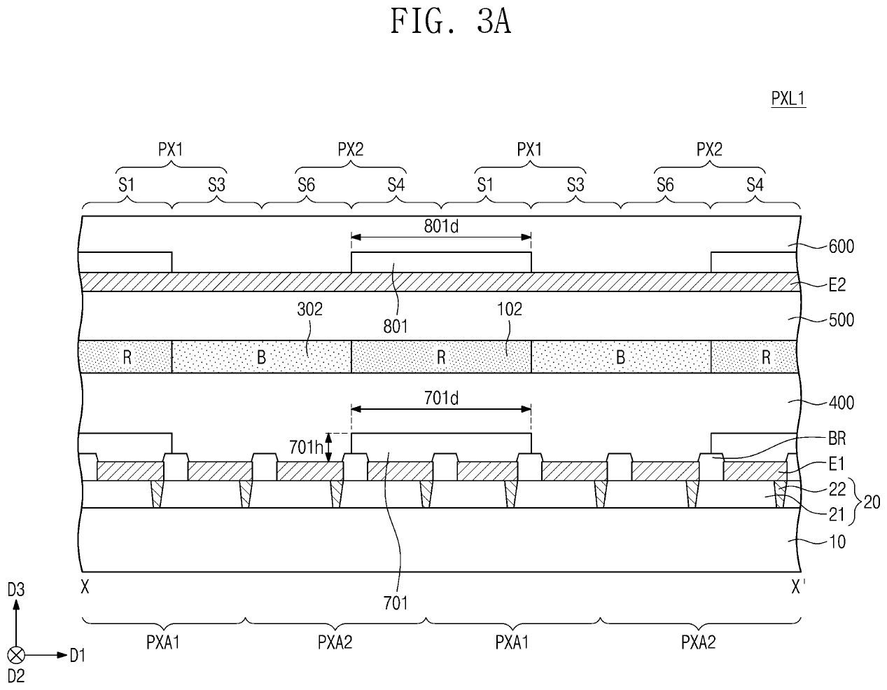

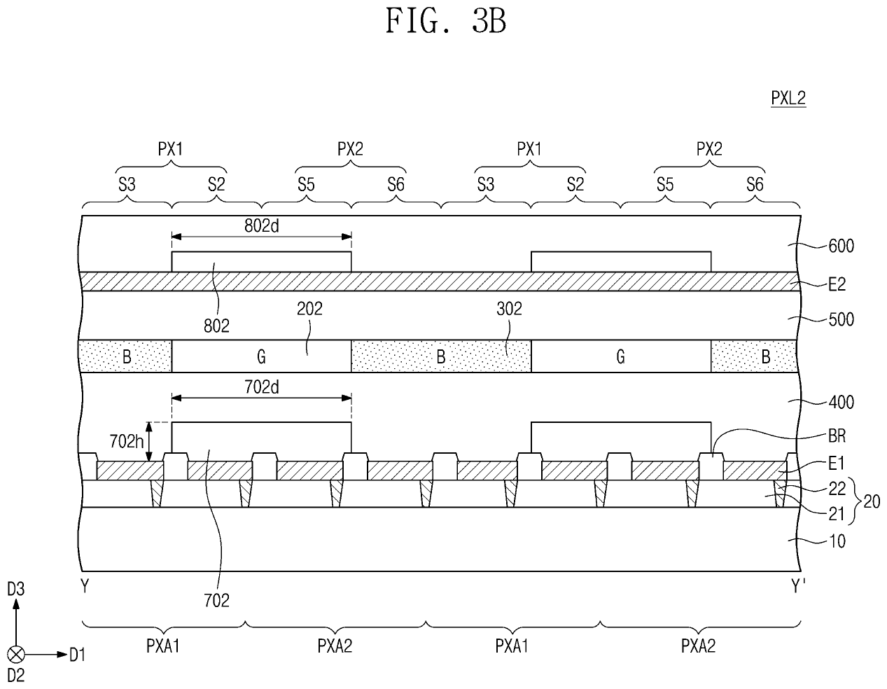

FIG. 3A is a cross-sectional view taken along line X-X′ of FIG. 1 according to some embodiments, FIG. 3B is a cross-sectional view taken along line Y-Y′ of FIG. 1 according to some embodiments. Since the above-described contents have been described in FIGS. 2A and 2B except for following contents to be described below, the duplicated contents will be omitted.

Referring to FIGS. 1, 3A, and 3B, a display device according to some embodiments may further include first and second resonance control patterns 701 and 702 and first and second reflection control patterns 801 and 802, which vertically overlap the red emission pattern 102 and the green emission pattern 202. The blue emission pattern 302 may not vertically overlap the first and second resonance control patterns 701 and 702 and the first and second reflection control patterns 801 and 802.

Each of the first resonance control patterns 701 may be provided on four first electrodes E1 that vertically overlap the red emission pattern 102. The four first electrodes E1 may be spaced apart from the first common layer 400 with the first resonance control pattern 701 therebetween.

Each of the second resonance control patterns 702 may be selectively provided on the four first electrodes E1 that vertically overlap the green emission pattern 202. The four first electrodes E1 may be spaced apart from the first common layer 400 with the first resonance control pattern 701 therebetween.

Each of the first reflection control patterns 801 may be provided on the second electrode E2 that vertically overlaps the red emission pattern 102. Each of the second reflection control patterns 802 may be selectively provided on the second electrode E2 that vertically overlaps the green emission pattern 202.

Each of the first and second resonance control patterns 701 and 702 may include at least one of an organic semiconductor layer, a transparent conductive material, or a transparent insulating material. For example, each of the resonance control patterns 701 and 702 may be a single layer including a transparent conductive material. As another example, each of the resonance control layer patterns 701 and 702 may be a double layer in which an insulating layer including a transparent insulating material and a conductive layer including a transparent conductive material are sequentially laminated (not shown). The organic semiconductor layer may include an acrylic resin, a polyimide resin, a novolak-type phenolic resin, and the like. The transparent conductive material may include indium tin oxide (ITO) or indium zinc oxide (IZO). The transparent insulating material may include an inorganic thin film such as SiO₂ or SiNx.

The first and second resonance patterns 701 and 702 may have substantially the same refractive index. For example, each of the resonance control layers may have a refractive index of about 1.6 to about 1.9.

Each of the first and second reflection control patterns 801 and 802 may include insulating layers including at least one of a transparent conductive material (TCO) such as ITO and IZO that are capable of transmitting light or a semi-transmissive conductive material such as magnesium (Mg), silver (Ag), or an alloy of magnesium (Mg) and silver (Ag) or an insulating material such as SiO/SiN, SiO₂/organic thin film, and the like. The insulating layers may be formed by laminating insulating layers having different refractive indexes. Thus, each of the first and second reflection control patterns 801 and 802 may have high reflectance. For example, each of the first and second reflection control patterns 801 and 802 may have reflectance of about 40% to about 80%.

A width 701d of the first resonance control pattern 701 in the first direction D1 (or the second direction D2) may be substantially the same as the width 102d of the red emission pattern 102 in the first direction D1 (or the second direction D2). This may also be equally applied to a relationship between the second resonance control pattern 702 and the green light emission pattern 202, a relationship between the first reflection control pattern 801 and the red light emission pattern 102, and a relationship between the second reflection control pattern 802 and the green light emission pattern 202.

That is, the planar area of each of the first resonance control pattern 701 and the first reflection control pattern 801 may be greater about 4 times than that of the red sub-pixel R, and each of the widths 701d and 801d of the first resonance control pattern 701 and the first reflection control pattern 801 may be greater about twice than the width ΔP1 of the red sub-pixel R.

The planar area of each of the second resonance control pattern 702 and the second reflection control pattern 802 may be greater about 4 times than that of the green sub-pixel G, and each of the widths 702d and 802d of the second resonance control pattern 702 and the second reflection control pattern 802 may be greater about twice than the width ΔP1 of the green sub-pixel G.

A thickness 701h of the first resonance control pattern 701 and a thickness 702h of the second resonance control pattern 702 may be different from each other. For example, the thickness 701h of the first resonance control pattern 701 may be less than the thickness 702h of the second resonance control pattern 702. As another example, the thickness 701h of the first resonance control pattern 701 may be greater than the thickness 702h of the second resonance control pattern 702.

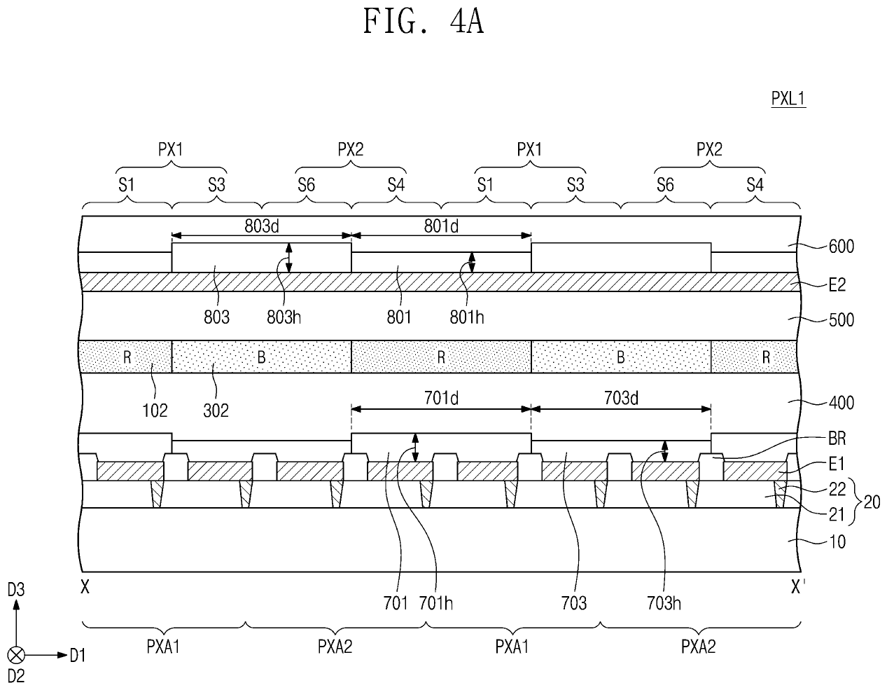

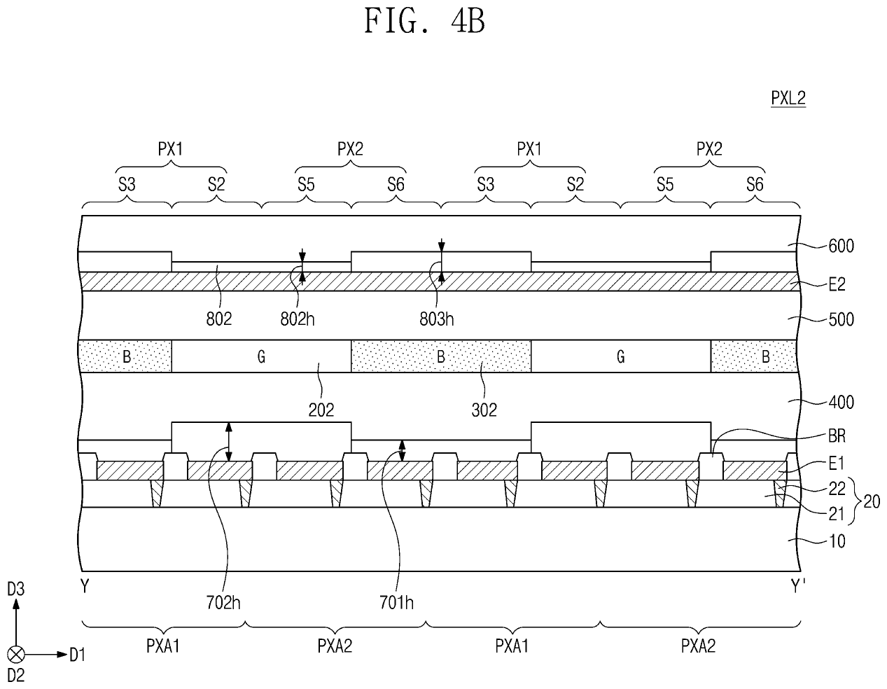

FIG. 4A is a cross-sectional view taken along line X-X′ of FIG. 1 according to some embodiments. FIG. 4B is a cross-sectional view taken along line Y-Y′ of FIG. 1 according to some embodiments. Since the above-described contents have been described in FIGS. 3A and 3B except for following contents to be described below, the duplicated contents will be omitted.

The display device according to some embodiments may further include a third resonance control pattern 703 and a third reflection control pattern 803, which vertically overlap the blue emission pattern 302. A planar area of each of the third resonance control pattern 703 and the third reflection control pattern 803 may be greater about 4 times than that of the blue sub-pixel B, and each of widths 703d and 803d of the third resonance control pattern 703 and the third reflection control pattern 803 may be greater about twice than the width ΔP1 of the blue sub-pixel B.

A thickness 703h of the third resonance control pattern 703 and each of thicknesses 701h and 702h of the first and second resonance control patterns 701 and 702 may be different from each other. A thickness 803h of the third reflection control pattern 803 and each of thicknesses 801h and 802h of the first and second resonance control patterns 801 and 802 may be the same as or different from each other.

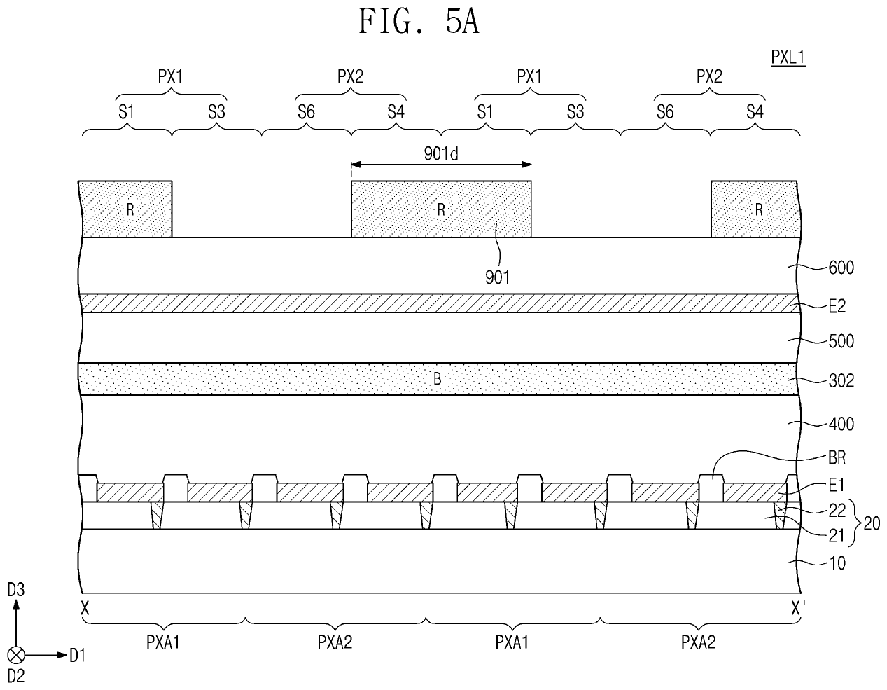

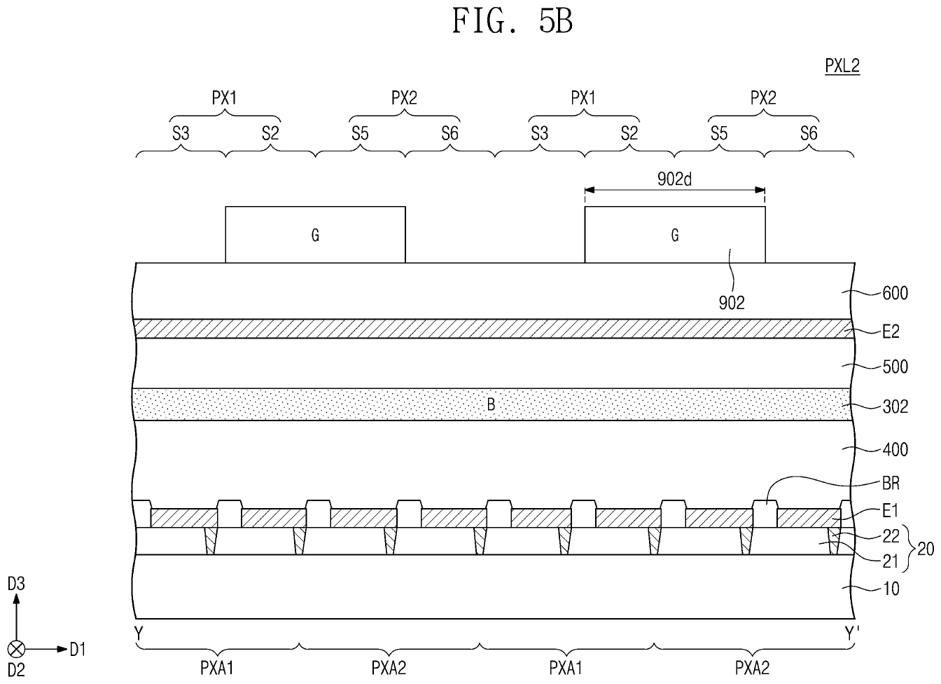

FIG. 5A is a cross-sectional view taken along line X-X′ of FIG. 1 according to some embodiments. FIG. 5B is a cross-sectional view taken along line Y-Y′ of FIG. 1 according to some embodiments. Since the above-described contents have been described in FIGS. 2A and 2B except for following contents to be described below, the duplicated contents will be omitted.

Referring to FIGS. 1, 5A, and 5B, the red emission pattern 102 and the green emission pattern 202 of FIGS. 2A and 2B may be omitted. The blue light emitting pattern 302 may extend and be disposed on the entire top surface of the substrate 10.

Instead of the red light emitting pattern 102 and the green light emitting pattern 202, a red conversion pattern 901 and a green conversion pattern 902 may be provided on the thin-film encapsulation layer 600. For example, the red sub-pixel R includes one first electrode E1, a blue emission layer 302 that vertically overlaps the one first electrode E1, a second electrode E2, and a red conversion pattern 901. The green sub-pixel G includes one first electrode E1, a blue emission layer 302 that vertically overlaps the one first electrode E1, a second electrode E2, and a green conversion pattern 902.

Each of the red conversion pattern 901 and the green conversion pattern 902 may be made of a quantum dot, a perovskite material, an inorganic phosphor, or a combinations thereof, which absorbs blue light to emit red and green light. Each of the red emission pattern 102 and the green emission pattern 202 may include nanoparticles of several hundred nm or less, and the nanoparticles may improve color conversion efficiency.

A planar area of the red conversion pattern 901 may be greater about four times than that of the red sub-pixel R, and a width 901d of the red conversion pattern 901 may be greater about twice than the width ΔP1 of the red sub-pixel R. A planar area of the green transition pattern 902 may be greater about four times than that of the green sub-pixel G, and a width 902d of the green transition pattern 902 may be greater about twice than the width ΔP1 of the green sub-pixel G.

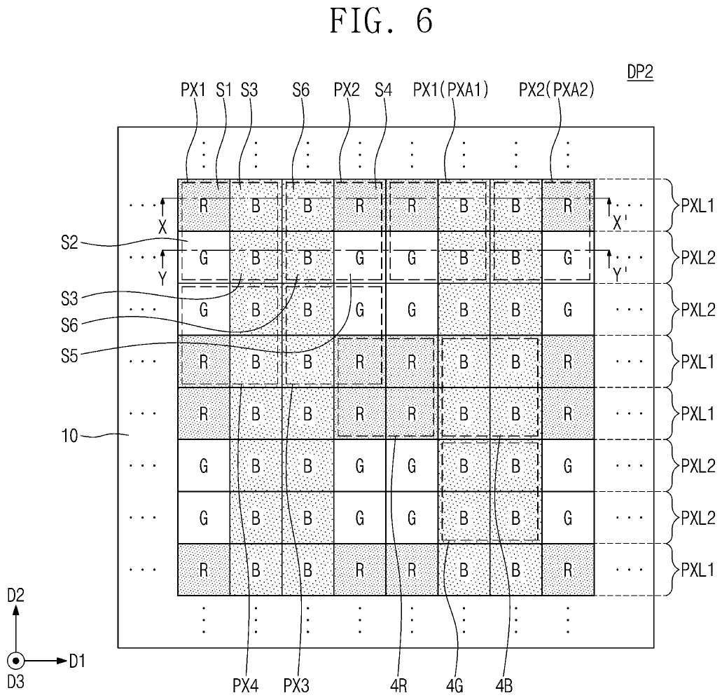

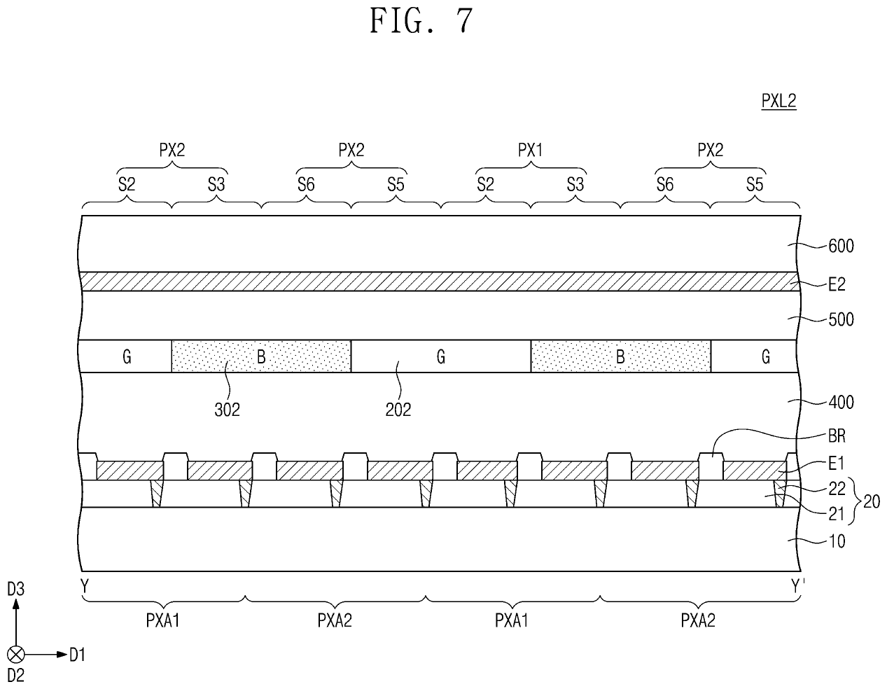

FIG. 6 is a plan view of a display device according to embodiments of the inventive concept. FIG. 7 is a cross-sectional view taken along line Y-Y′ of FIG. 6. Since the above-described contents have been described in FIGS. 2A and 2B except for following contents to be described below, the duplicated contents will be omitted. (cross-sectional view taken along line X-X′ is the same as that of FIG. 2A and thus will be omitted)

Referring to FIG. 6, in the first pixel PX1, the third sub-pixels S3 may be continuously disposed in the second direction D2. That is, the third sub-pixels S3 may be disposed in different rows and the same column. Also, the first sub-pixel S1 and the second sub pixel S2 may be disposed in different rows and the same column.

In the second pixel PX2, the sixth sub-pixels S6 may be continuously disposed in the second direction D2. That is, the sixth sub-pixels S6 may be disposed in different rows and the same column. Also, the fourth sub-pixel S4 and the fifth sub-pixel S5 may be disposed in different rows and the same column.

All of the third sub-pixels S3 may be disposed adjacent to all of the sixth sub-pixels S6 in the first direction D1. The first sub-pixel S1 may be spaced apart from the fourth sub-pixel S4 in the first direction D1 with the third sub-pixel S3 and the sixth sub-pixel S6 therebetween. The second sub-pixel S2 may be spaced apart from the fourth sub-pixel S5 in the first direction D1 with the third sub-pixel S3 and the sixth sub-pixel S6 therebetween.

The arrangement of the first sub-pixel S1, the second sub-pixel S2, and the third sub-pixels S3 may have a line symmetry relationship and a mirror image relationship with respect to the arrangement between the fourth sub-pixel S4, the fifth sub-pixel S5, and the sixth sub-pixels, based on a virtual line between the first pixel PX1 and the second pixel PX2.

The two blue sub-pixels B of one first pixel line PXL1 may be disposed adjacent to the two blue sub-pixels B of the second pixel line PXL2 in the second direction D2. The two red sub-pixels R of one first pixel line PXL1 may be disposed adjacent to the two green sub-pixels G of the second pixel line PXL2 in the second direction D2.

Four red sub-pixels 4R, four green sub-pixels 4R, and four blue sub-pixels 4B, which are disposed adjacent to each other by the arrangement of the pair of first pixel lines PXL1 and the pair of second pixel lines PXL2, may be provided. Each of the four red sub-pixels 4R, the four green sub-pixels 4R, and the four blue sub-pixels 4B may be arranged in a 2×2 matrix form.

In the case of the existing deposition process, since the width of the sub-pixel is substantially equal to a width of an opening of a shadow mask, it is difficult to control patterning as the width of the pixel to be formed is more fine. In the display device according to an embodiment of the inventive concept, the emission pattern may be formed to be greater about twice or about 4 times than the sub-pixel pitch through the shadow mask. In the case of the deposition process using the shadow mask (for example, a fine metal mask), the smaller the width of the pixel to be formed, the more difficult it is to control the patterning. Thus, the light emitting material may be deposited with the double width or the planar area that is greater 4 times than the existing planar area, the desired width of the pixel may be more fine. As a result, it is possible to implement a high-resolution display device by forming the red pixel, the green pixel, and the blue pixels, which have fine widths. This may be applied not only to the emission pattern but also to the resonance control pattern, the reflectance control pattern, and the color conversion pattern, thereby improving the high resolution performance of the high-resolution display device.

The red pixel may implement a red pixel having a fine width by forming the red conversion pattern on a portion of the green emission pattern and a portion of the blue emission pattern using a photolithography process.

According to the embodiments of the inventive concept, the pixel arrangement may be adjusted to implement the display device having the high resolution.

Although the embodiment of the inventive concept is described with reference to the accompanying drawings, those with ordinary skill in the technical field of the inventive concept pertains will be understood that the present disclosure can be carried out in other specific forms without changing the technical idea or essential features. Therefore, the above-disclosed embodiments are to be considered illustrative and not restrictive.

What is claimed is:

1. A display device comprising:
a substrate; and
a first pixel and a second pixel, which are disposed adjacent to each other in a first direction parallel to a top surface of the substrate and are alternately and repeatedly arranged,
wherein the first pixel comprises a first sub-pixel, a second sub-pixel, and two third sub-pixels, which are arranged in a 2×2 matrix form,
the second pixel comprises a fourth sub-pixel, a fifth sub-pixel, and two sixth sub-pixels, which are arranged in a 2×2 matrix form,
the first to third sub-pixels comprise sub-pixels having colors different from each other,
the fourth to sixth sub-pixels comprise sub-pixels having colors different from each other,
the first sub-pixel and the fourth sub-pixel comprise sub-pixels having the same color,
the second sub-pixel and the fifth sub-pixel comprise sub-pixels having the same color,
the third sub-pixels and the sixth sub-pixels comprise sub-pixels having the same color, and
the first pixel and the second pixel have a line symmetry relationship based on a virtual line between the first pixel and the second pixel.

2. The display device of claim 1, wherein the third sub-pixels are disposed in different rows and different columns, and
the sixth sub-pixels are disposed in different rows and different columns.

3. The display device of claim 1, wherein the first sub-pixel and the second sub-pixels are disposed in different rows and different columns, and
the fourth sub-pixel and the fifth sub-pixels are disposed in different rows and different columns.

4. The display device of claim 1, wherein one of the third sub-pixels is disposed adjacent to one of the sixth sub-pixels in the first direction, and
the other of the third sub-pixels and the other of the sixth sub-pixels are disposed to be spaced apart from each other in the first direction with the second sub-pixel and the fifth sub-pixel therebetween.

5. The display device of claim 1, wherein the second sub-pixel and the fifth sub-pixel are disposed adjacent to each other in the first direction.

6. The display device of claim 1, wherein the third sub-pixels are disposed in different rows and the same column,
the sixth sub-pixels are disposed in different rows and the same column, and
the third sub-pixels and the sixth sub-pixels are disposed adjacent to each other.

7. The display device of claim 1, wherein the first sub-pixel and the second sub-pixel are disposed in different rows and the same column, and
the fourth sub-pixel and the fifth sub-pixel are disposed in different rows and the same column.

8. A display device comprising:
a substrate;
a pair of first pixel lines disposed adjacent to each other in a first direction parallel to a top surface of the substrate; and
a pair of second pixel lines disposed adjacent to each other in the first direction,
wherein one of the first pixel lines is disposed adjacent to one of the first pixel lines in the first direction, and the first pixel lines and the second pixel lines are alternately and repeatedly arranged in the first direction,
each of the first pixel lines comprises two red sub-pixels and two first blue sub-pixels, which are alternately and repeatedly arranged in a second direction that is parallel to the top surface of the substrate and crosses the first direction, and
each of the second pixel lines comprises two second blue sub-pixels and two green sub-pixels, which are alternately and repeatedly arranged in the second direction.

9. The display device of claim 8, wherein the red sub-pixels of the pair of first pixel lines are disposed adjacent to each other in a 2×2 matrix form,
the blue sub-pixels of the pair of first pixel lines are disposed adjacent to each other in a 2×2 matrix form,
the green sub-pixels of the pair of second pixel lines are disposed adjacent to each other in a 2×2 matrix form, and
the blue sub-pixels of the pair of second pixel lines are disposed adjacent to each other in a 2×2 matrix form.

10. The display device of claim 8, wherein one blue sub-pixel of the first pixel lines is adjacent to one blue sub-pixel of the second pixel lines in a diagonal direction.

11. The display device of claim 10, wherein one blue sub-pixel of the first pixel lines is adjacent to one blue sub-pixel of the second pixel lines in the first direction.

12. The display device of claim 11, wherein one red sub-pixel of the first pixel lines is adjacent to one green sub-pixel of the second pixel lines in the first direction.

13. A display device comprising:
a substrate;
a plurality of first electrodes arranged in a matrix form on the substrate;
a red emission pattern, a green emission pattern, and a blue emission pattern, which are disposed on the first electrodes; and
a second electrode disposed on the red, green, and blue emission patterns,
wherein the red emission pattern vertically overlaps four first electrodes, which are disposed adjacent to each other in a first direction parallel to a top surface of the substrate, a second direction parallel to the top surface of the substrate and crossing the first direction, and a third direction between the first direction and the second direction,
the green emission pattern vertically overlaps four first electrodes, which are disposed adjacent to each other in the first direction, the second direction, and the third direction, and
the blue emission pattern vertically overlaps four first electrodes, which are disposed adjacent to each other in the first direction, the second direction, and the third direction.

14. The display device of claim 13, further comprising:
a common layer between the plurality of first electrodes and the red, green, and blue emission patterns;
a first resonance control pattern and a second resonance control pattern between the plurality of first electrodes and the common layer; and
a first reflection control pattern and a second reflection control pattern on the second electrode,
wherein the first resonance control pattern and the first reflection control pattern are provided on the four first electrodes that vertically overlap the red emission pattern, and
the second resonance control pattern and the second reflection control pattern are provided on the four first electrodes that vertically overlap the green emission pattern.

15. The display device of claim 14, wherein a thickness of the first resonance control pattern and a thickness of the second resonance control pattern are different from each other.

16. The display device of claim 14, further comprising:
a third resonance control pattern disposed between the plurality of first electrodes and the common layer; and
a third reflection control pattern provided on the second electrode,
wherein the third resonance control pattern and the third reflection control pattern are provided on the four first electrodes that vertically overlap the blue emission pattern.

17. The display device of claim 13, further comprising a first pixel, a second pixel, a third pixel, and a fourth pixel, which are arranged in a clockwise direction in a 2×2 matrix form on the top surface of the substrate,
wherein each of the first to fourth pixels comprises one first red sub-pixel, one green sub-pixel, and two blue sub-pixels, which are arranged in a 2×2 matrix form, and
the sub-pixels having the same color of each of the first to fourth pixels are disposed adjacent to each other based on a central point at which the first pixel, the second pixel, the third pixel, and the fourth pixel are gathered.

18. The display device of claim 17, wherein the first pixel and the second pixel have a line symmetry relationship based on a virtual line between the first pixel and the second pixel,
the first pixel and the third pixel have a point symmetry relationship based on a virtual point between the first pixel and the third pixel, and
the first pixel and the fourth pixel have a line symmetry relationship based on a virtual line between the first pixel and the fourth pixel.
